(19) United States
(12) Patent Application Publication
(10) Pub. No.: US 2016/0248455 A1
(43) Pub. Date: Aug. 25, 2016

(54) POP FREE AUTO-CHOPPER

(71) Applicant: QUALCOMM Incorporated, San Diego, CA (US)

(72) Inventor: Vijayakumar Dhanasekaran, San Diego, CA (US)

(21) Appl. No.: 14/628,930

(22) Filed: Feb. 23, 2015

(51) Int. Cl. H04B 1/04; H03F 3/38

(52) U.S. Cl. CPC H04B 1/0475; H03F 3/38; H03F 2200/271; H04B 2001/0416

(57) ABSTRACT

Embodiments described herein provide a method and apparatus for increasing dynamic range. The method begins when a signal is input to a compander and the compander gain of the signal is measured. The compander gain level is then compared with a predetermined threshold. If the compander gain is less than the predetermined threshold, then the chopper is turned on. If the chopper is already operating as a result of a previous iteration, then it remains on after the comparison. If the compander gain is above the predetermined threshold, the chopper is turned off. The device incorporates an automatic chopper and a duty cycle shaper to provide smooth ramp up of the automatic chopper, eliminating chopper turn on sounds.

### FIELD

The present disclosure relates generally to wireless communication systems, and more particularly to a method and apparatus for improving the dynamic range using a pop free automatic amplifier chopper.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms.

A wireless communication system may support communication for multiple wireless communication devices at the same time. In use, a wireless communication device may communicate with one or more base stations by transmissions on the uplink and downlink. Base stations may be referred to as access points, Node Bs, or other similar terms. The uplink or reverse link refers to the communication link from the wireless communication device to the base station, while the downlink or forward link refers to the communication from the base station to the wireless communication devices.

Wireless communication systems may be multiple access systems capable of supporting communication with multiple users by sharing the available system resources, such as bandwidth and transmit power. Examples of such multiple access systems include code division multiple access (CDMA) systems, time division multiple access (TDMA) systems, frequency division multiple access (FDMA) systems, wideband code division multiple access (WCDMA) systems, global system for mobile (GSM) communication systems, enhanced data rates for GSM evolution (EDGE) systems, and orthogonal frequency division multiple access (OFDMA) systems.

Mobile devices typically incorporate at least one amplifier to aid in transmitting signals over the air. Amplifiers may produce noise at various frequencies, such as 1/f noise, and may also produce offset noise. A chopper may be used in amplifiers to reduce the 1/f noise and offset. However, adding a chopper may introduce additional problems, such as degradation of the high frequency linearity of the amplifier and may also cause total harmonic distortion and/or intermodulation distortion at high frequencies. In addition, there may be second order intermodulation distortion folding of any delta-sigma quantization noise.

The chopper may still be needed to improve noise reduction and offset, despite the difficulties noted above. There is a need in the art for a method and apparatus to provide for adaptive turning on and off an amplifier chopper to enhance the amplifier dynamic range.

### SUMMARY

Embodiments described herein provide a method for increasing dynamic range. The method begins when a signal is input to a compander and the compander gain of the signal is measured. The compander gain level is then compared with a predetermined threshold. If the compander gain is less than the predetermined threshold, then the chopper is turned on. If the chopper is already operating as a result of a previous iteration, then it remains on after the comparison. If the compander gain is above the predetermined threshold, the chopper is turned off.

A further embodiment provides an apparatus for increasing dynamic range. The apparatus incorporates a variable amplifier, which is in communication with a digital to analog converter (DAC). The DAC is in communication with a chopper amplifier. A compander is in communication with the variable amplifier and an automatic chopper. The apparatus may also include a duty cycle shaper to provide ramp shaping for turn on signals used to cycle the automatic chopper on or off.

A still further embodiment provides an apparatus for increasing dynamic range. The apparatus incorporates: means for measuring compander gain; means for determining if the compander gain is greater than a predetermined threshold; means for automatically turning on a chopper if the compander gain is less than the predetermined threshold; and means for automatically turning off a chopper if the compander gain is greater than the predetermined threshold.

An additional embodiment provides a non-transitory computer-readable medium containing instructions, which cause a processor to perform the steps of: measuring compander gain; determining if the compander gain is greater than a predetermined threshold; automatically turning on a chopper if the compander gain is less than the predetermined threshold; and automatically turning off a chopper if the compander gain is greater than the predetermined threshold.

### BRIEF DESCRIPTION OF THE DRAWINGS

FIG. 1 illustrates a wireless multiple-access communication system, in accordance with certain embodiments of the disclosure.

FIG. 2 is a block diagram of a wireless communication system in accordance with embodiments of the disclosure.

FIG. 3 is a block diagram for an auto-chopper, in accordance with embodiments of the disclosure.

FIG. 4 is a block diagram of a pop-free auto chopper in accordance with certain embodiments of the disclosure.

FIG. 5 illustrates a duty cycle shaping mechanism in accordance with certain embodiments of the disclosure.

FIG. 6 shows the performance improvement for an analog amplifier in accordance with certain embodiments of the disclosure.

FIG. 7 shows the performance improvement for a digital amplifier in accordance with certain embodiments of the disclosure.

FIG. 8 is a flow diagram of a method for improving dynamic range using a pop-free automatic chopper on an amplifier, in accordance with certain embodiments of the disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

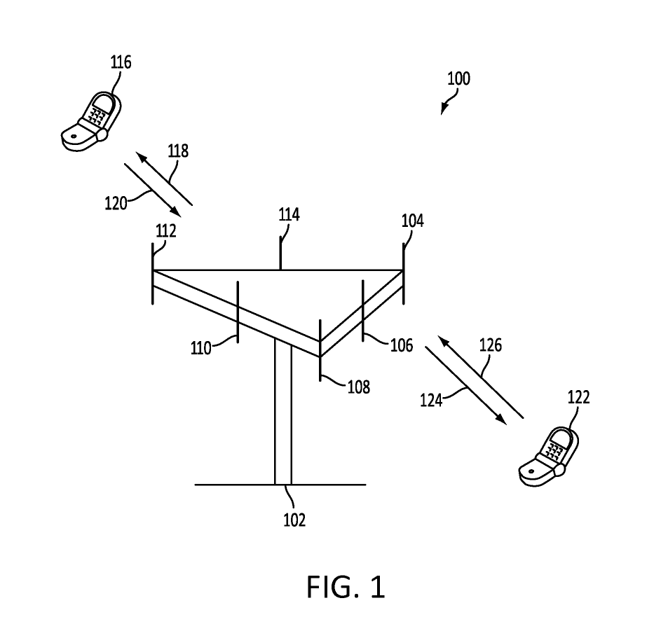

FIG. 1 illustrates a multiple access wireless communication system 100 according to one aspect. An access point 102 (AP) includes multiple antenna groups, one including 104 and 106, another including 108 and 110, and an additional one including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over downlink or forward link 118 and receive information from access terminal 116 over uplink or reverse link 120. Access terminal 122 is in communication with antennas 106 and 108, where antennas 106 and 108 transmit information to access terminal 122 over downlink or forward link 124, and receive information from access terminal 122 over uplink or reverse link 126. In a frequency division duplex (FDD) system, communication link 118, 120, 124, and 126 may use a different frequency for communication. For example, downlink or forward link 118 may use a different frequency than that used by uplink or reverse link 120.

Each group of antennas and/or the area in which they are designed to communicate is often referred to as a sector of the access point. In an aspect, antenna groups are each designed to communicate to access terminals in a sector of the areas covered by access point 102.

In communication over downlinks or forward links 118 and 124, the transmitting antennas of an access point utilize beamforming in order to improve the signal-to-noise ration (SNR) of downlinks or forward links for the different access terminals 116 and 122. Also, an access point using beamforming to transmit to access terminals scattered randomly through its coverage causes less interference to access terminals in neighboring cells than an access point transmitting through a single antenna to all its access terminals.

An access point may be a fixed station used for communicating with the terminals and may also be referred to as a Node B, an evolved Node B (eNB), or some other terminology. An access terminal may also be called a mobile station, user equipment (UE), a wireless communication device, terminal or some other terminology. For certain aspects, either the AP 102, or the access terminals 116, 122 may utilize the techniques described below to improve performance of the system.

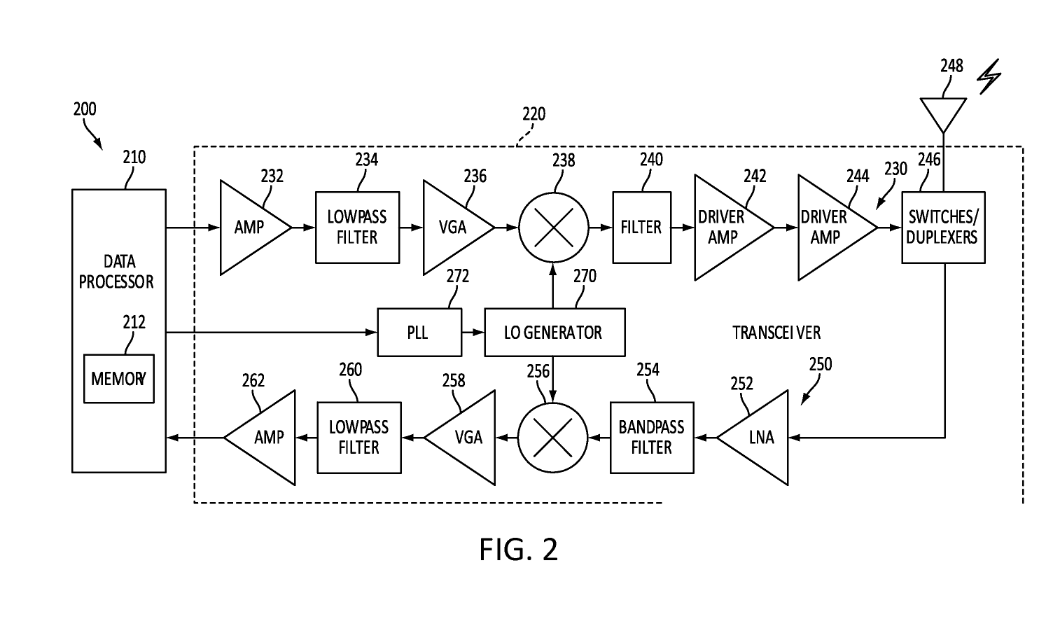

FIG. 2 shows a block diagram of an exemplary design of a wireless communication device 200. In this exemplary design, wireless device 200 includes a data processor 210 and a transceiver 220. Transceiver 220 includes a transmitter 230 and a receiver 250 that support bi-directional wireless communication. In general, wireless device 200 may include any number of transmitters and any number of receivers for any number of communication systems and any number of frequency bands.

In the transmit path, data processor 210 processes data to be transmitted and provides an analog output signal to transmitter 230. Within transmitter 230, the analog output signal is amplified by an amplifier (Amp) 232, filtered by a lowpass filter 234 to remove images caused by digital-to-analog conversion, amplified by a VGA 236, and upconverted from baseband to RF by a mixer 238. The upconverted signal is filtered by a filter 240, further amplified by a driver amplifier, 242 and a power amplifier 244, routed through switches/duplexers 246, and transmitted via an antenna 249.

In the receive path, antenna 248 receives signals from base stations and/or other transmitter stations and provides a received signal, which is routed through switches/duplexers 246 and provided to receiver 250. Within receiver 250, the received signal is amplified by an LNA 252, filtered by a bandpass filter 254, and downconverted from RF to baseband by a mixer 256. The downconverted signal is amplified by a VGA 258, filtered by a lowpass filter 260, and amplified by an amplifier 262 to obtain an analog input signal, which is provided to data processor 210.

FIG. 2 shows transmitter 230 and receiver 250 implementing a direct-conversion architecture, which frequency converts a signal between RF and baseband in one stage. Transmitter 230 and/or receiver 250 may also implement a super-heterodyne architecture, which frequency converts a signal between RF and baseband in multiple stages. A local oscillator (LO) generator 270 generates and provides transmit and receive LO signals to mixers 238 and 256, respectively. A phase locked loop (PLL) 272 receives control information from data processor 210 and provides control signals to LO generator 270 to generate the transmit and receive LO signals at the proper frequencies.

FIG. 2 shows an exemplary transceiver design. In general, the conditioning of the signals in transmitter 230 and receiver 250 may be performed by one or more stages of amplifier, filter, mixer, etc. These circuits may be arranged differently from the configuration shown in FIG. 2. Some circuits in FIG. 2 may also be omitted. All or a portion of transceiver 220 may be implemented on one or more analog integrated circuits (ICs), RF ICs (RFICs), mixed-signal ICs, etc. For example, amplifier 232 through power amplifier 244 in transmitter 230 may also be implemented on an RFIC. Driver amplifier 242 and power amplifier 244 may also be implemented on another IC external to the RFIC.

Data processor 210 may perform various functions for wireless device 200, e.g., processing for transmitter and received data. Memory 212 may store program codes and data for data processor 210. Data processor 210 may be implemented on one or more application specific integrated circuits (ASICs) and/or other ICs.

Wireless devices such as those described in FIG. 2 also incorporate amplifiers to aid in transmitting and receiving of signals. In many instances, a chopper is used in conjunction with an amplifier. A chopper is a static device that converts fixed direct current (DC) input to a variable DC output voltage directly. The chopper behaves like an alternating current (AC) transformer. Essentially, a chopper is an electronic switch used to interrupt one signal that is under the control of another signal.

Chopper amplifiers are DC amplifiers. In some cases, the signals being amplified may be so small that a very high gain is required, however, very high gain amplifiers may be difficult to build with a low offset and 1/f noise, reasonable stability, and bandwidth. A chopper circuit is used to break up the input signal so that it may be processed as an AC signal, and then integrated back to a DC signal at the output. Even small DC signals may be amplified this way, making a chopper amplifier useful in devices such as wireless devices or smartphones. In particular, chopper amplifiers provide increased dynamic range, which is desirable for use with peripheral devices such as headphones, or other line out devices.

While choppers are traditionally used to reduce 1/f noise and offset there are undesirable side effects as the chopper degrades the high frequency linearity of the amplifier. This degradation may cause total harmonic distortion (THD) and may also cause intermodulation distortion (IMD) at high frequencies. This may result in second order intermodulation (IM2) folding of the delta-sigma modulator quantization noise. Problems for users arise when this noise lands in the audio band, appearing as a noisy or unintelligible signal.

Embodiments described herein provide a method and apparatus for adaptively turning on or off an amplifier chopper. If the compander analog gain is less than a predetermined threshold, the chopper is turned on. This is done to minimize system noise at low signal levels. If the compander gain is greater than a predetermined threshold the chopper is turned off. This helps minimize distortion and noise folding at high signal levels. The embodiments described herein provide the flexibility to utilize the chopper when it enhances performance and gives the ability to turn the chopper off when it will hurt device performance.

If the chopper is turned on or off abruptly, a fast fading signal may produce an audible “pop”. This pop is caused by the chopper turning on at a low gain level, which drops the power amplifier output from an offset voltage (Voffset). Voffset may be up to 800 μV. As a result, Voffset may drop to nearly 0 volts. This drop causes the audible pop with no nearby signal to mask the sound.

A further embodiment uses duty cycle shaping to gradually turn on the chopper. In this embodiment, the output is gradually shaped from the Voffset to 0 volts, in a manner similar to start up waveform shaping. In operation the wave generate then generated an s-shaped waveform. The ramp generator generates a ramp at the clock rate of the chopper. Duty cycle shaping is then provided by the comparator output.

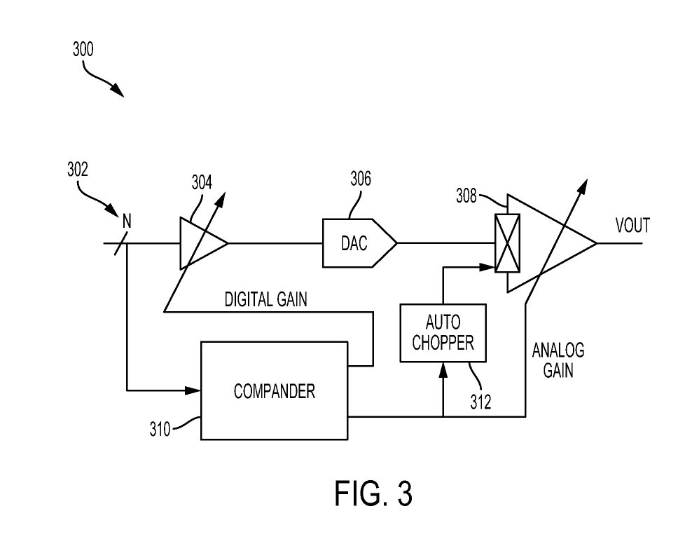

FIG. 3 illustrates a system for signal processing incorporating an auto chopper. The assembly 300 includes a digital input signal N 302. Signal N 302 is input to a variable amplifier 304. The output from amplifier 304 is input to digital to analog converter (DAC) 306. After conversion the signal is then input to chopper amplifier 308. Chopper amplifier 308 also receives input from compander 310 and auto chopper 312. In addition, signal N 302 is also input to compander 310. Compander 310 also provides digital gain input to variable amplifier 304.

A compander such as compander 310, is used to mitigate the detrimental effects of a channel with a limited dynamic range. The process is known as companding. Companding allows signals with a large dynamic range, such as music or conversations, to be transmitted over facilities with a limited dynamic range. In addition, companding permits more information to be transmitted in a more efficient manner. In companding a non-linear compression of the signal occurs. This compression takes place in the same manner at all points in time. The signal is then transmitted in the compressed form. At the receiver, the signal is then expanded back to the original value.

Compander 310 works by compressing or expanding the dynamic range of a signal, often an analog signal. However, digital signals may also be companded. This compression may be done with multiple amplifiers: a logarithmic amplifier, followed by a variable gain linear amplifier, and an exponential amplifier. This combination of amplifiers provides an output voltage that is proportional to the input voltage raised to an adjustable power.

Companded quantization is the combination of three functional building blocks: a continuous domain signal dynamic range compressor, a limited range uniform quantizer, and a continuous domain signal dynamic range expander that inverts the compression waveform. Companding may be used in digital telephony systems, compressing a signal before the input to a digital to analog converter (DAC) as shown in FIG. 3, with compander 310 providing input to variable amplifier 304, prior to DAC 306.

In operation, the assembly 300 of FIG. 3 monitors the compander 310 analog gain. A predetermined threshold is established for the operating conditions and is used in conjunction with assembly 300. If the compander 310 analog gain is less than the predetermined threshold, auto chopper 312 turns on chopper amplifier 308. This minimizes system noise when signal levels are low. If the compander 310 analog gain is greater than the predetermined threshold, then auto chopper 312 turns chopper amplifier 308 off. This minimizes distortion in the signal and also minimizes noise folding when signal levels are high.

While the auto chopper 312 described above provides increased dynamic range, additional signal and noise problems may still arise. If the auto chopper 312 is abruptly turned on or off, a fast fading signal may produce an audible “pop” sound. The pop sound occurs because the auto chopper 312 turning on at a low gain level reduces the power output from the variable power amplifier 304 from the offset voltage Voffset. Voffset may be up to 800 μV. The auto chopper 312 turning on reduces Voffset from the 800 μV to nearly 0V. The result of this abrupt reduction is an audible pop that occurs when there is no nearby signal to mask the sound.

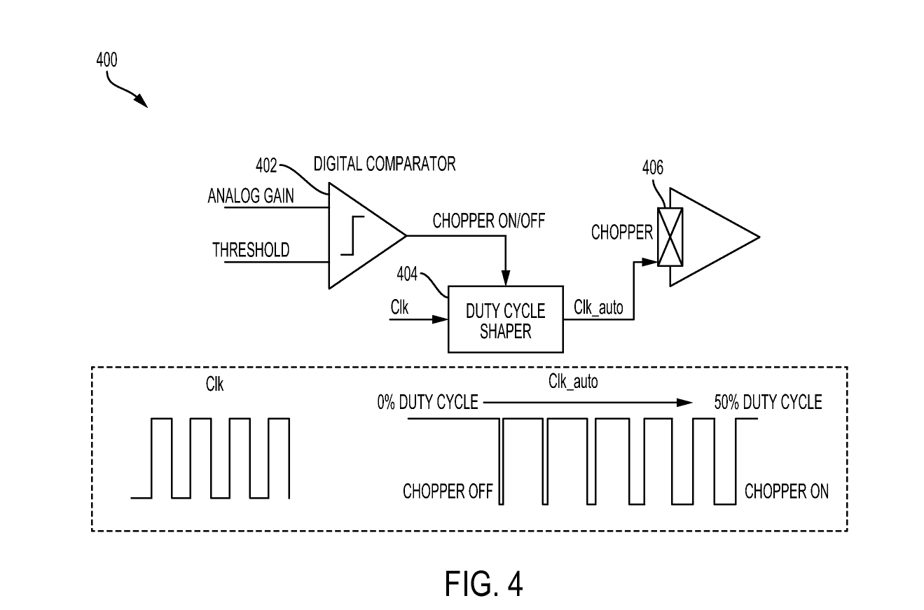

FIG. 4 depicts a further embodiment that provide a pop free auto chopper. The assembly 400 includes a digital comparator 402, which is connected to a duty cycle shaper 404. Digital comparator 402 receives two inputs, an analog gain input and a threshold value input. The output from duty cycle shaper 404 is input to chopper amplifier 406. Duty cycle shaper 404 provides for a gradual turn on of auto chopper 312. In operation auto chopper 312 multiplies the signal by a series of +1 values and −1 values. If the pulse width is equal, then auto chopper 312 is partially on. When the value is +1 the chopper merely passes the signal. When the value is −1 the signal is an inverse signal that may cancel the undesired pop sound. The duty cycle shaper 404 provides for the output to be gradually shaped from the Voffset to 0V, in a manner similar to start up waveform shaping. This action results in a smooth ramp-up that is quiet with no pop.

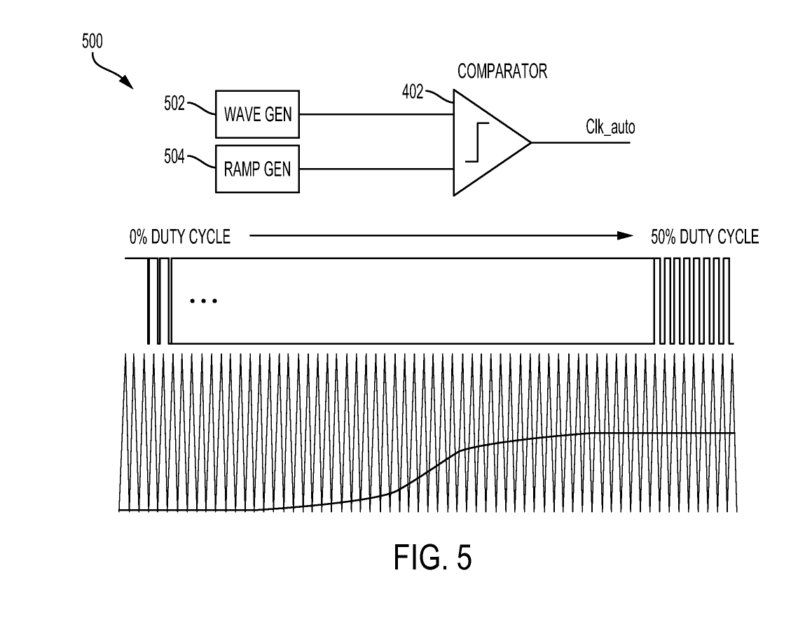

FIG. 5 provides further implementation details of the duty cycle shaper 404. The assembly 500 includes two inputs to comparator 402. The first input is from waveform generator 502. The second input is ramp generator 504. Waveform generator 502 generates an s-shaped waveform. One example of a generated waveform is a second order integration. Ramp generator 504 generates a ramp at the clock rate of the auto chopper 312. The output from comparator 402 provides the necessary duty cycle shaping as illustrated in the waveform and clock duty cycles in FIG. 5. The embodiment may be used with either digital or analog circuits. For digital circuits, additional embodiments may use a look-up table or compute the values needed. The duty cycle shaper provides a flexible mechanism for adjusting as needed to avoid annoying and loud “pop” signals and also provides a gradual increase in density.

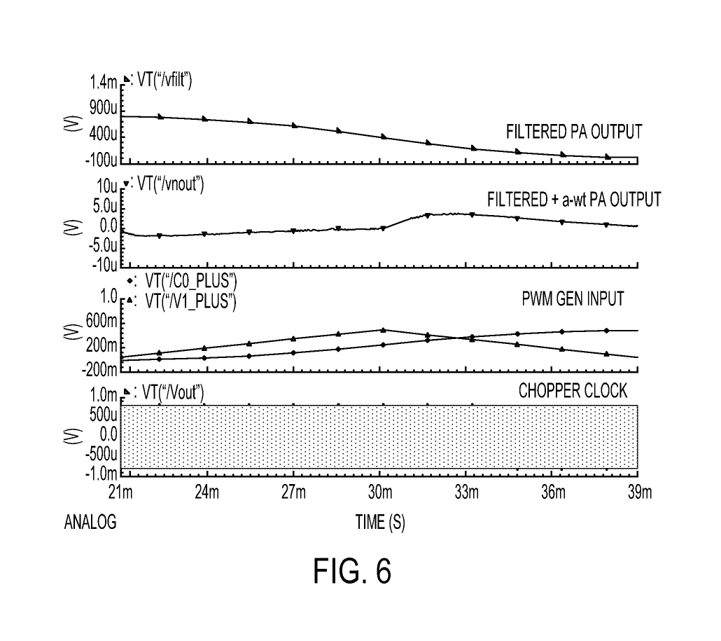

FIG. 6 shows how the embodiments described above improve performance when an analog signal is used. With the embodiments described herein the pop signal is reduced from 800 μV to 5 μV. This signal is not sufficiently strong to produce a pop that annoys a listener and reduces performance.

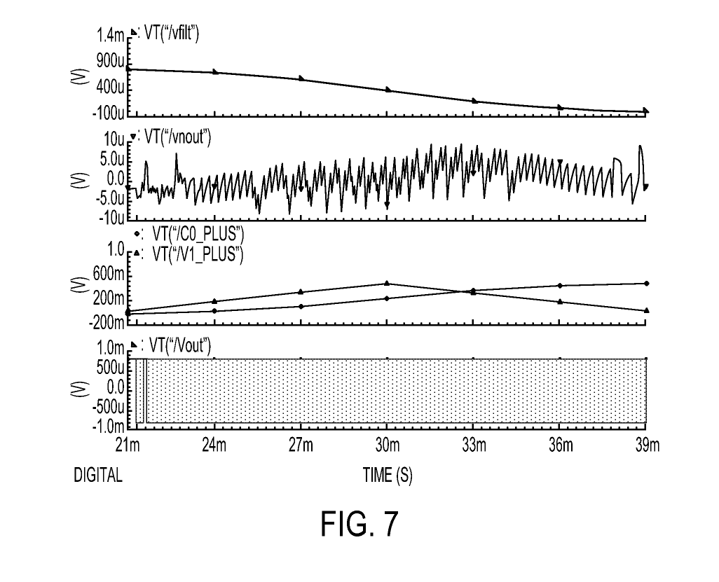

FIG. 7 shows how the embodiments described above improve performance when a digital audio signal is used. In the digital example shown, the pop is reduced from 800 μV to 13 μV. Multiple glitches are limited by a 9.6 MHz master clock, MCLK.

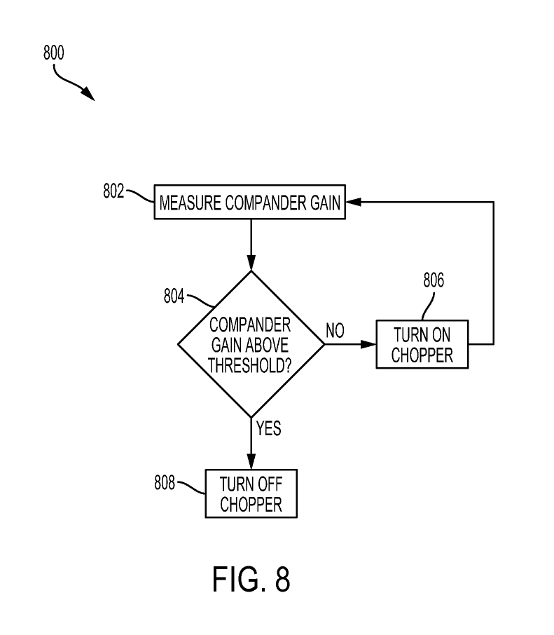

FIG. 8 is a flow diagram of a method for improving dynamic range using a pop-free automatic chopper on an amplifier, in accordance with certain embodiments of the disclosure. The method 800 begins when a signal is input to a compander. In step 802 the compander gain is measured. The measured compander gain is then compared with a predetermined threshold in step 804. If the compander gain is not above the predetermined threshold the chopper is turned on in step 806. If the chopper is already on as a result of a previous iteration, then the chopper remains on. If the compander gain is above the predetermined threshold, the chopper is turned off in step 808.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

1. A method of increasing dynamic range, comprising:
measuring compander gain;
determining if the compander gain is greater than a predetermined threshold;
automatically turning on a chopper if the compander gain is less than the predetermined threshold to increase dynamic range of the signal; and
automatically turning off a chopper if the compander gain is greater than the predetermined threshold to increase the dynamic range of the signal.

2. The method of claim 1, wherein the chopper is turned on over a period of time.

3. The method of claim 2, wherein an output of a digital comparator is shaped by the chopper over a period of time to reduce a voltage value from an offset voltage value down to zero voltage.

4. The method of claim 3, wherein the output of the digital comparator is shaped in accordance with a predetermined curve function.

5. The method of claim 4, wherein the predetermined curve function is an s-shaped curve.

6. The method of claim 4, wherein the predetermined curve function is selected based on a location of a second order harmonic signal.

7. The method of claim 5, wherein the s-shaped curve is generated at a clock rate of the chopper.

8. The method of claim 4, wherein the s-shaped curve is retrieved from a look-up table.

9. The method of claim 3, wherein the digital comparator provides duty cycle shaping of a turn on function of the chopper.

10. An apparatus for increasing dynamic range, comprising:
a variable amplifier, in communication with a digital to analog converter (DAC);
the DAC in communication with a chopper amplifier; and
a compander in communication with the variable amplifier and an automatic chopper.

11. The apparatus for increasing dynamic range of claim 10, wherein the compander provides digital gain input to the variable amplifier.

12. The apparatus for increasing dynamic range of claim 11, wherein the automatic chopper provides input to the chopper amplifier.

13. An apparatus for increasing dynamic range, comprising:
a variable amplifier, in communication with a digital to analog converter (DAC);
the DAC in communication with a chopper amplifier;
a compander in communication with the variable amplifier and an automatic chopper;
a digital comparator in communication with a duty cycle shaper; and
the duty cycle shaper in communication with the chopper amplifier.

14. The apparatus for increasing dynamic range of claim 13, wherein the comparator provides chopper on and off information to the duty cycle shaper.

15. The apparatus for increasing dynamic range of claim 14, wherein the duty cycle shaper provides input to the chopper amplifier.

16. An apparatus for increasing dynamic range, comprising:
means for measuring compander gain;
means for determining if the compander gain is greater than a predetermined threshold;
means for automatically turning on a chopper if the compander gain is less than the predetermined threshold; and
means for automatically turning off a chopper if the compander gain is greater than the predetermined threshold.

17. The apparatus of claim 16, further comprising means for turning on the chopper over a period of time.

18. An apparatus for increasing dynamic range, comprising;
means for measuring compander gain;
means for determining if the compander gain is greater than a predetermined threshold;
means for automatically turning on a chopper if the compander gain is less than the predetermined threshold;
means for automatically turning off a chopper if the compander gain is greater than the predetermined threshold;
means for turning on the chopper over a period of time; and
means for shaping on output of a digital comparator over a period of time.

19. The apparatus of claim 17, further comprising means for shaping an output of the digital comparator in accordance with a predetermined curve function.

20. The apparatus of claim 19, further comprising means for storing the predetermined curve function.

21. The apparatus of claim 19, further comprising means for generating the predetermined curve function at a clock rate of the chopper.

22. The apparatus of claim 16, further comprising: means for duty cycle shaping a turn on function of the chopper.

23. A non-transitory computer-readable medium containing instructions, which when executed cause a processor to perform the steps of:
measuring compander gain;
determining if the compander gain is greater than a predetermined threshold;
automatically turning on a chopper if the compander gain is less than the predetermined threshold; and
automatically turning off a chopper if the compander gain is greater than the predetermined threshold.

24. The non-transitory computer-readable medium of claim 23, further comprising instructions for turning on the chopper over a period of time.

25. A non-transitory computer-readable medium containing instructions, which when executed cause a processor to perform the steps of:
measuring compander gain;
determining if the compander gain is greater than a predetermined threshold;
automatically turning on a chopper if the compander gain is less than the predetermined threshold;
automatically turning off a chopper if the compander gain is greater than the predetermined threshold;
further comprising instructions for turning on the chopper over a period of time; and
shaping an output of a digital compander over a period of time to reduce a voltage value from an offset voltage value to zero voltage.

26. The non-transitory computer readable medium of claim 25, further comprising instructions for shaping the output of the digital comparator in accordance with a predetermined curve function.

27. The non-transitory computer-readable medium of claim 26, further comprising instructions for generating a ramp up signal for the chopper at a clock rate of the chopper.

28. The non-transitory computer-readable medium of claim 23, further comprising instructions for duty cycle shaping of a turn on function of the chopper.
